(19) United States
(12) Patent Application Publication
(10) Pub. No.: US 2008/0179041 A1
(43) Pub. Date: Jul. 31, 2008

(54) Heat dissipating device for heat dissipation of an electronic component

(75) Inventors: Jen-Lu Hu, Tainan City (TW); Hao-Hui Lin, Taitung City (TW); Tsung-Ching Lin, Tainan City (TW); Su-Chen Hu, Tainan City (TW)

Correspondence Address: DLA PIPER US LLP, 2000 UNIVERSITY AVENUE, E. PALO ALTO, CA, 94303-2248, US

(73) Assignee: Man Zai Industrial Co., Ltd.

(21) Appl. No.: 11/701,024

(22) Filed: Jan. 31, 2007

(51) Int. Cl. H05K 7/20

(52) U.S. Cl. 165/71; 165/80.4; 361/699

(57) ABSTRACT

A heat dissipating device includes a heat sink, a pump connected to the heat sink, and a radiator connected to the heat sink and the pump. The radiator includes spaced apart first and second side tanks. The second side tank defines an inner space therein and is formed with a coolant-refilling opening in fluid communication with the inner space. The radiator further includes a cap mounted removably on the second side tank for closing sealingly the coolant-refilling opening, a plurality of conduits interconnecting and in fluid communication with the first and second side tanks, and a fin structure disposed between the first and second side tanks and connected to the first and second side tanks and the conduits.

### BACKGROUND OF THE INVENTION

1. Field of the Invention

The invention relates to a heat dissipating device for an electronic component, more particularly to a heat dissipating device including a radiator having a coolant refilling opening covered by a cap.

2. Description of the Related Art

As shown in FIG. 1, a conventional heat dissipating device, adapted to be in contact with a heat source (not shown), such as a CPU or a heat-generating component of a display for heat dissipation, generally includes a radiator 11, an inlet conduit 12, an outlet conduit 13, a heat sink 14, and a pump 15. The heat sink 14 includes a fluid inlet 141 and a fluid outlet 142. The radiator 11 includes a coolant inlet 112 and a coolant outlet 111. The inlet conduit 12 interconnects the fluid inlet 141 of the heat sink 14 and the coolant outlet 111 of the radiator 11. The outlet conduit 13 interconnects the fluid outlet 142 of the heat sink 14 and the coolant inlet 112 of the radiator 11. The pump 15 is mounted on the inlet conduit 12, and the inlet conduit 12 has a first conduit section 121 interconnecting the coolant outlet 111 and the pump 15, and a second conduit section 122 interconnecting the pump 15 and the fluid inlet 141.

When the pump 15 is operated, a coolant in the radiator 11 flows through the first conduit section 121, the second conduit section 122, the fluid inlet 141 and enters the heat sink 14. After conducting heat exchange to absorb heat from the heat source, the high-temperature coolant flows through the fluid outlet 142, the outlet conduit 13 and the coolant inlet 112 into the radiator 11 to complete a circulation cycle.

Although the conventional heat dissipating device has the heat dissipating effect, there is still a disadvantage: An undesired high coolant vaporizing rate due to connection between the pump 15 and the first and second conduit sections 121, 122 of the inlet conduit 12 occurs, which not only diminishes the heat dissipating effect, but also causes potential hazard in use when the amount of the coolant in the radiator 11 becomes too low.

### SUMMARY OF THE INVENTION

Therefore, the object of the present invention is to provide a heat dissipating device that can overcome the aforesaid disadvantage associated with the prior art.

Accordingly, there is provided a heat dissipating device for heat dissipation of an electronic component. The heat dissipating device comprises: a heat sink adapted to be attached to the electronic component and having a fluid inlet and a fluid outlet; a pump connected to the fluid inlet of the heat sink; and a radiator formed with a coolant inlet connected to the fluid outlet of the heat sink, and a coolant outlet connected to the pump. The radiator includes spaced apart first and second side tanks. The second side tank defines an inner space therein and is formed with a coolant-refilling opening in fluid communication with the inner space. The radiator further includes a cap mounted removably on the second side tank for closing sealingly the coolant-refilling opening, a plurality of conduits interconnecting and in fluid communication with the first and second side tanks so as to permit fluid circulation through the first and second side tanks and the heat sink, and a fin structure disposed between the first and second side tanks and connected to the first and second side tanks and the conduits.

### BRIEF DESCRIPTION OF THE DRAWINGS

Other features and advantages of the present invention will become apparent in the following detailed description of the preferred embodiment with reference to the accompanying drawings, of which:

FIG. 1 is a schematic view of a conventional heat dissipating device;

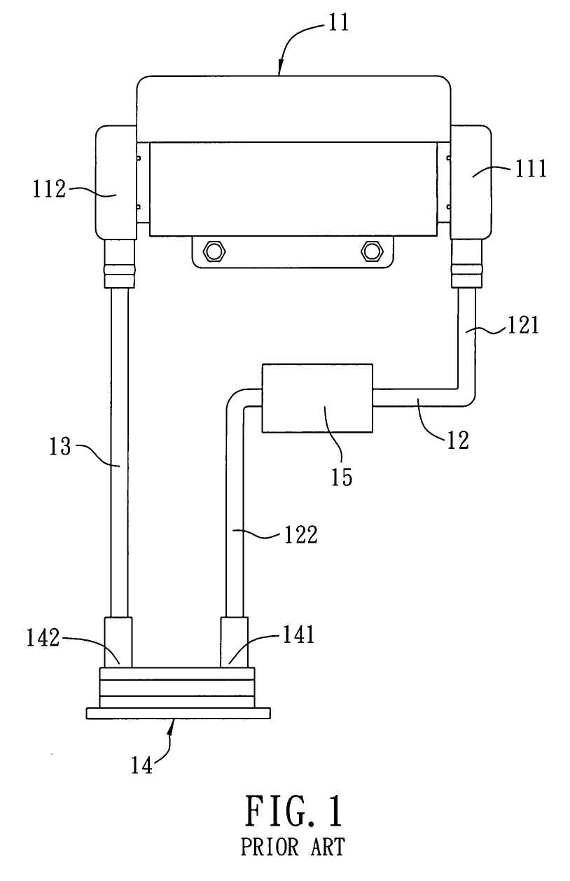

FIG. 2 is a schematic view of the preferred embodiment of a heat dissipating device according to this invention;

FIG. 3 is an exploded perspective view of a radiator of the preferred embodiment; and

FIG. 4 is a sectional view of the radiator of the preferred embodiment.

### DETAILED DESCRIPTION OF THE PREFERRED EMBODIMENT

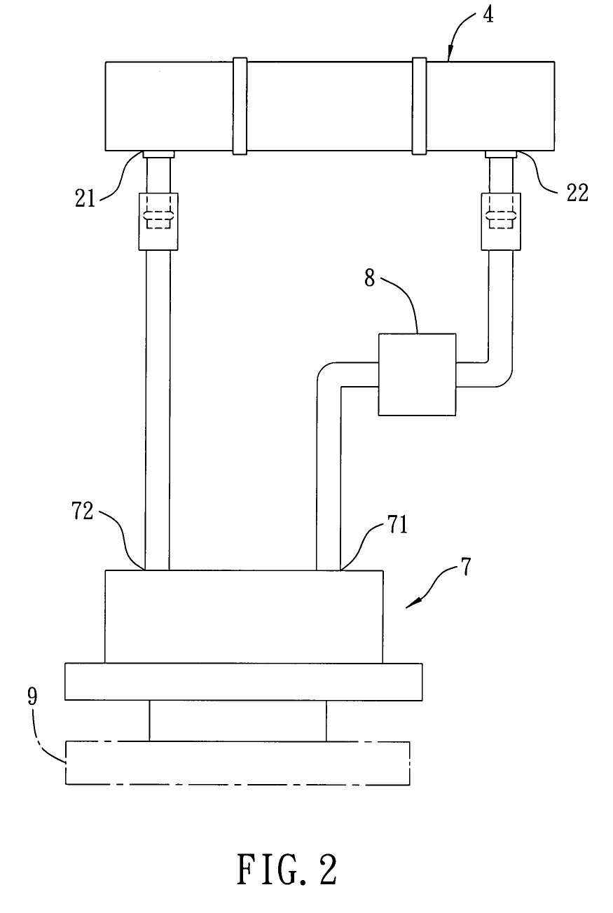

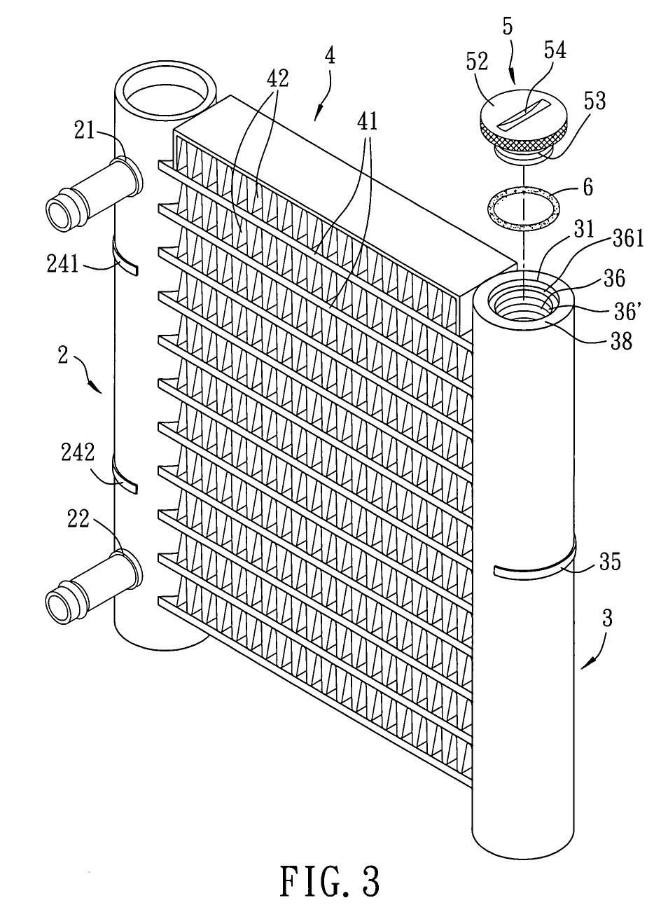

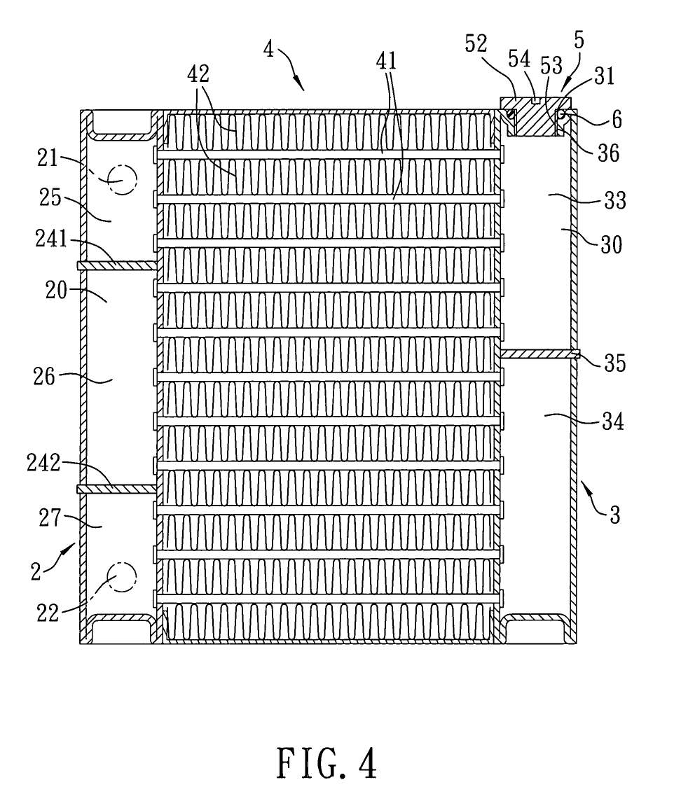

Referring to FIGS. 2 to 4, the preferred embodiment of a heat dissipating device according to the present invention is shown to be adapted to be connected to an electronic component 9, and to include: a heat sink 7 adapted to be attached to the electronic component 9 and having a fluid inlet 71 and a fluid outlet 72; a pump 8 connected to the fluid inlet 71 of the heat sink 7; and a radiator 4 formed with a coolant inlet 21 connected to the fluid outlet 72 of the heat sink 7, and a coolant outlet 22 connected to the pump 8. The radiator 4 includes spaced apart first and second side tanks 2, 3. The second side tank 3 defines an inner space 30 therein and is formed with a coolant-refilling opening 31 in fluid communication with the inner space 30. The radiator 4 further includes a cap 5 mounted removably on the second side tank 3 for closing sealingly the coolant-refilling opening 31, a plurality of conduits 41 interconnecting and in fluid communication with the first and second side tanks 2, 3 so as to permit fluid circulation through the first and second side tanks 2, 3 and the heat sink 7, and a fin structure 42 disposed between the first and second side tanks 2, 3 and connected to the first and second side tanks 2, 3 and the conduits 41. In this embodiment, the coolant inlet 21 and the coolant outlet 22 are both formed on the first side tank 2.

The coolant-refilling opening 31 in the second side tank 3 is defined by an opening-defining wall 36′ that is formed with an inner thread 36. The cap 5 has an outer thread 53 that extends into the coolant-refilling opening 31 and that engages threadedly the inner thread 36.

The opening-defining wall 36′ is further formed with a shoulder 361. The cap 5 further has a head 52 enlarged in diameter from the outer thread 53, and is formed with an elongate groove 54 in the head 52. The radiator 4 further includes an O-ring 6 seated on the shoulder 361 of the opening-defining wall 36′ and abutting sealingly against the shoulder 361 and the head 52 of the cap 5.

Each of the first and second side tanks 2, 3 is cylindrical in shape. The second side tank 3 has an open end 38 in which the coolant-refilling opening 31 is formed.

The first side tank 2 defines an inner space 20 therein, and is provided with first and second partitioning walls 241, 242 that cooperatively divide the inner space 20 in the first side tank 2 into first, second, and third chambers 25, 26, 27. The second side tank 3 is provided with a third partitioning wall 35 that divides the inner space 30 in the second side tank 3 into fourth and fifth chambers 33, 34. The coolant-refilling opening 31 is in fluid communication with the fourth chamber 33. The coolant inlet 21 is in fluid communication with the first chamber 25. The coolant outlet 22 is in fluid communication with the third chamber 27. The fourth chamber 33 is in fluid communication with the first chamber 25 through respective ones of the conduits 41. The second chamber 26 is in fluid communication with the fifth chamber 34 through respective ones of the conduits 41. The fifth chamber 34 is in fluid communication with the third chamber 27 through respective ones of the conduits 41.

In use, the coolant in the first side tank 2 of the radiator 4 is withdrawn by the pump 8 and is subsequently delivered into the heat sink 7 so as to absorb heat from the electronic component 9. The heated coolant is then returned to the first side tank 2 to be cooled by heat dissipation through the fin structure 42 of the radiator 4.

A liquid level sensor (not shown) is installed on the radiator 4 for monitoring the level of the coolant in the radiator 4.

By forming the coolant-refilling opening 31 in the second side tank 3 of the radiator 4 of the heat dissipating device of this invention, the radiator 4 can be refilled with the coolant when the level of the coolant in the radiator 4 is low, thereby eliminating the aforesaid drawback associated with the prior art.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. A heat dissipating device for heat dissipation of an electronic component, said heat dissipating device comprising:
a heat sink adapted to be attached to the electronic component and having a fluid inlet and a fluid outlet;
a pump connected to said fluid inlet of said heat sink; and
a radiator formed with a coolant inlet connected to said fluid outlet of said heat sink, and a coolant outlet connected to said pump, said radiator including
spaced apart first and second side tanks, said second side tank defining an inner space therein and being formed with a coolant-refilling opening in fluid communication with said inner space,
a cap mounted removably on said second side tank for closing sealingly said coolant-refilling opening,
a plurality of conduits interconnecting and in fluid communication with said first and second side tanks so as to permit fluid circulation through said first and second side tanks and said heat sink, and
a fin structure disposed between said first and second side tanks and connected to said first and second side tanks and said conduits.

2. The heat dissipating device as claimed in claim 1, wherein said coolant-refilling opening is defined by an opening-defining wall that is formed with an inner thread, said cap having an outer thread that extends into said coolant-refilling opening and that engages threadedly said inner thread.

3. The heat dissipating device as claimed in claim 2, wherein said opening-defining wall is further formed with a shoulder, said cap further having a head enlarged in diameter from said outer thread, said radiator further including an O-ring seated on said shoulder of said opening-defining wall and abutting sealingly against said shoulder and said head of said cap.

4. The heat dissipating device as claimed in claim 3, wherein said second side tank is cylindrical in shape and has an open end in which said coolant-refilling opening is formed.

5. The heat dissipating device as claimed in claim 4, wherein said first side tank defines an inner space therein, and is provided with first and second partitioning walls that cooperatively divide said inner space in said first side tank into first, second, and third chambers, said second side tank being provided with a third partitioning wall that divides said inner space in said second side tank into fourth and fifth chambers, said coolant-refilling opening being in fluid communication with said fourth chamber, said coolant inlet being in fluid communication with said first chamber, said coolant outlet being in fluid communication with said third chamber, said fourth chamber being in fluid communication with said first chamber through respective ones of said conduits, said second chamber being in fluid communication with said fifth chamber through respective ones of said conduits, said fifth chamber being in fluid communication with said third chamber through respective ones of said conduits.
